(19) United States
(12) Patent Application Publication
(10) Pub. No.: US 2007/0059912 A1
(43) Pub. Date: Mar. 15, 2007

(54) Method of forming metal silicide layer and related method of fabricating semiconductor devices

(76) Inventors: Jong-ho Yun, Suwon-si (KR); Byung-hee Kim, Seoul (KR); Eun-ji Jung, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/519,845

(22) Filed: Sep. 13, 2006

(30) Foreign Application Priority Data
Sep. 15, 2005 (KR) 10-2005-0086362

(51) Int. Cl. H01L 21/4763

(52) U.S. Cl. 438/592; 438/630; 438/649

(57) ABSTRACT

A method of forming a composite metal silicide layer is disclosed in which a PVD-metal layer is deposited on a silicon layer using a Physical Vapor Deposition (PVD) process, and is substantially simultaneously silicidated to form a PVD-metal silicide layer. Un-reacted portions of the PVD-metal layer are then removed and a CVD-metal layer is formed on the PVD-metal silicide layer using a Chemical Vapor Deposition (CVD) process. A first heat treatment is performed to silicidate a portion of the CVD-metal layer contacting the PVD-metal silicide layer and thereby form a composite metal silicide layer. Un-reacted residual portions of the CVD-metal layer are removed and a second heat treatment is performed on the composite metal silicide layer at a higher temperature than the first heat treatment.

### BACKGROUND OF THE INVENTION

1. Field of the Invention

Embodiments of the invention relate to a method of forming a metal silicide layer and a related method of fabricating a semiconductor device.

This application claims priority from Korean Patent Application No. 10-2005-0086362 filed on Sep. 15, 2005, the subject matter of which is hereby incorporated by reference in its entirety.

2. Description of the Related Art

A continuing demand exists for semiconductor devices having increased integration density, higher operating speed, and lower power consumption. Integration density is generally increased by reducing the size of the circuit patterns defining the implementation layout of a semiconductor device. For example, circuit pattern line widths, junction depths for source/drain regions, cross-sectional contact areas, etc., may all be reduced is size by ongoing attempts to increase density. However, reductions in circuit patterns and the size of corresponding elements within a semiconductor design come at considerable consequence. For example, reductions in circuit pattern may increase resistances in a semiconductor device. Left without remedy, increased resistance reduces operating speed and increases power consumption.

In an attempt to remedy these problems, the use of metal silicide has been proposed as a replacement for the polysilicon conventionally used. The term “metal silicide” refers to any compound containing both metal and silicon. Tungsten silicide, titanium silicide, or cobalt silicide are commonly used metal silicides. Cobalt silicide, in particular, has low specific resistance and stable thermal and chemical properties. Thus, cobalt silicide has been extensively used in the fabrication of semiconductor devices require a high speed operation, low power consumption, and/or high integration.

However, as with other semiconductor components, metal silicide layers have been reduced in size (e.g., width and/or thickness) under the influence continuing efforts to increase integration density. Unfortunately, the thermal stability of metal silicide layer becomes impaired when their size is reduced below certain tolerances (e.g., minimum widths and/or thicknesses) base on application.

Further, metal silicide layers may exhibit properties that vary with the manner of their formation (e.g., method of deposition). For example, a metal silicide layer formed by a physical vapor deposition (hereinafter, abbreviated to as PVD) process may suffer from agglomerated or fracture at high temperatures, thus increasing surface resistance of the metal silicide layer. On the other hand, a metal silicide layer formed by a chemical vapor deposition (hereinafter, referred to as CVD) process may suffer from junction characteristic deterioration (e.g., leakage current) between P+ type and N type regions, thus causing deterioration in the reliability of the constituent semiconductor device.

### SUMMARY OF THE INVENTION

In contrast to the foregoing, embodiments of the invention provide a method of forming a composite metal silicide layer that assures the reliability of a constituent semiconductor device. As such, embodiments of the invention are well suited for incorporation into an overall method of fabricating a semiconductor device.

In one embodiment, the invention provides a method of forming a composite metal silicide layer comprising; depositing a PVD-metal layer on a silicon layer using a Physical Vapor Deposition (PVD) process, and substantially simultaneously silicidating a portion of the PVD-metal layer contacting the silicon layer to form a PVD-metal silicide layer, removing an un-reacted portion of the PVD-metal layer, forming a CVD-metal layer on the PVD-metal silicide layer using a Chemical Vapor Deposition (CVD) process, performing a first heat treatment to silicidate a portion of the CVD-metal layer contacting the PVD-metal silicide layer and thereby form a composite metal silicide layer, removing an un-reacted residual portion of the CVD-metal layer, and performing a second heat treatment on the composite metal silicide layer, wherein the second heat treatment is performed at a higher temperature than the first heat treatment.

In another embodiment, the invention provides a method of fabricating a semiconductor device, comprising; forming a gate structure comprising a polysilicon layer formed on a gate insulating layer over a channel region separating source/drain regions formed in a silicon substrate, depositing a PVD-metal layer using a Physical Vapor Deposition (PVD) on upper surfaces of the polysilicon layer and the source/drain regions, and substantially simultaneously silicidating portions of the PVD-metal layer contacting the upper surfaces of the polysilicon layer and the source/drain regions to form a PVD metal silicide layer, removing un-reacted portions of the PVD-metal layer, forming a CVD-metal layer on the PVD-metal silicide layer, performing a first heat treatment to silicidate portions of the CVD-metal layer contacting the PVD-metal silicide layer to form a composite metal silicide layer, removing un-reacted portions of the CVD-metal layer, and performing a second heat treatment on the composite metal silicide layer, wherein the temperature of the second heat treatment is higher than the temperature of the first heat treatment.

In another embodiment, the invention provides a method of fabricating a semiconductor device, comprising; forming an interlayer dielectric on a silicon layer, etching the interlayer dielectric to form a contact hole exposing an upper surface of the silicon layer, forming a PVD-metal layer on the exposed upper surface of the silicon layer using a Physical Vapor Deposition (PVD) method, and substantially simultaneously silicidating a portion of the PVD-metal layer contacting the exposed upper surface of the silicon layer to form a PVD metal silicide layer, removing un-reacted portions of the PVD-metal layer, forming a CVD-metal layer on the PVD-metal silicide layer, performing a first heat treatment to silicidate a portion of the CVD-metal layer contacting the PVD-metal silicide layer to form a composite metal silicide layer, removing un-reacted portions of the CVD-metal layer, and performing a second heat treatment on the composite metal silicide layer, wherein the temperature of the second heat treatment is higher than the temperature of the first heat treatment.

### BRIEF DESCRIPTION OF THE DRAWINGS

Several embodiments of the invention will be described with reference to the accompany drawings in which:

FIG. 1 is a flowchart illustrating an exemplary method of forming a metal silicide layer according to an embodiment of the invention;

FIGS. 2A to 2G are sectional views sequentially illustrating a method of fabricating a semiconductor device according to the embodiment of the invention; and

FIGS. 3A to 3G are sectional views sequentially illustrating a method of fabricating a semiconductor device according to another embodiment of the invention.

### DESCRIPTION OF EMBODIMENTS

Advantages and features of the present invention and methods of accomplishing the same may be understood more readily by reference to the following description of embodiments and the accompanying drawings. The present invention may, however, be embodied in many different forms and should not be construed as being limited to only the embodiments set forth herein. Rather, these embodiments are provided as teaching examples. Like reference numerals refer to like elements throughout the specification.

Moreover, in the specification, the term “PVD-metal layer” denotes a layer having metal content (including metal alloy content) deposited by using a PVD process. The term “CVD-metal layer” denotes a layer having metal content (including metal alloy content) deposited by using CVD process, such as a metal organic chemical vapor deposition (MOCVD) method, or an atomic layer deposition (ALD) process. Furthermore, it is to be understood that the terms “PVD-metal silicide layer” and “CVD-metal silicide layer” denote silicide layers formed by any process “silicidating” a PVD-metal layer or a CVD-metal layer, respectively.

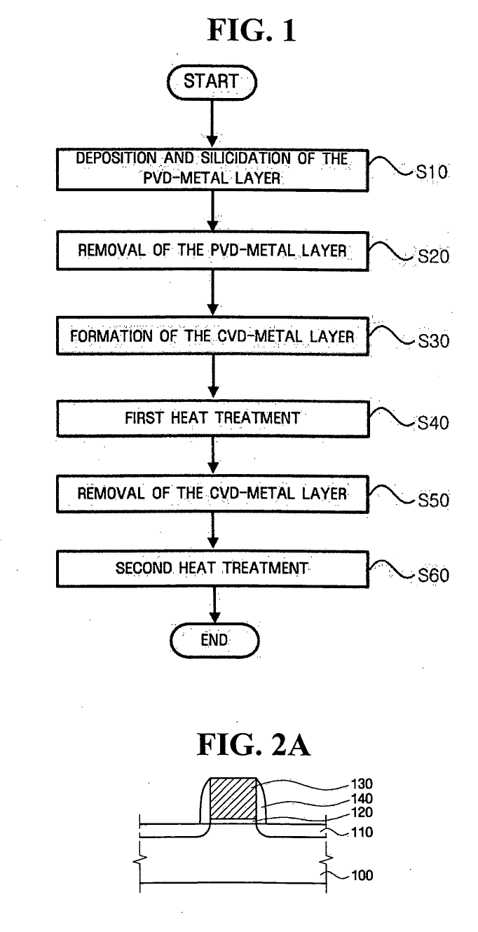

An exemplary method of forming a metal silicide layer according to an embodiment of the invention will now be described with reference to FIG. 1.

A PVD-metal layer is first deposited on a silicon layer (e.g., any substrate or material layer containing a silicon component) using a PVD method. This PVD-metal layer is then “silicidated” (i.e., a process is applied to convert the PVD-metal layer into a PVD-metal silicide layer). (S10).

At least one embodiment of the invention recognizes that PVD processes are typically conducted at high temperatures. Accordingly, a PVD-metal layer may be deposited on the silicon layer and, nearly simultaneously be silicidated, (e.g., reacted with the silicon component of the silicon layer on which it is formed). In one more specific embodiment, a predetermined PVD-metal silicide layer may be formed on the interface between a deposited PVD-metal layer and a silicon layer, and be interposed therebetween. Since the PVD-metal silicide layer is formed at nearly the same time (i.e., in immediate succession) as the metal layer deposition, without the requirement for a separately applied heat treatment, the PVD-metal silicide layer may be formed with reduced size (e.g., width and/or thickness) and with a more uniform film shape. For example, the PVD-metal silicide layer may be formed with a thickness ranging from between about 5 to 50 Å, and this formation thickness may be correspondingly controlled by deposition process conditions, such as a deposition temperature.

Additionally, the ultimate thickness of the resulting PVD-metal silicide layer is not directly determined by the deposition thickness of PVD-metal layer. Accordingly, the PVD-metal layer may be formed with less thickness precision. For example, the PVD-metal layer may be formed with a thickness ranging between about 5 to 300 Å, which is sufficient to realize the deposition of a good quality, continuous film. That is, in the case of a PVD-metal silicide layer formed using a high temperature PVD process, it is unnecessary for the PVD-metal layer to be formed to an ultimately desired thickness. Thus, the corresponding process margin may be improved. Additionally, it is possible to form a PVD-metal silicide layer having a continuous surface, instead of merely forming island-type layers, as is conventional. Finally, a PVD-metal silicide layer formed as described above will avoid the excessive silicidation that often occurs during subsequently applied heat treatments, as will be described in some additional detail below. As a result, thinner metal silicide layers may be accurately formed.

For example, a PVD-metal layer may be formed from components such as Co, Ti, and Ni, as selected examples without implying any limitation. Furthermore, the temperature of the PVD process may be correspondingly controlled in accordance with the type of metal layer to be deposited, (i.e., in accordance with one or more PVD-metal layer components). For example, in the case of cobalt, a deposition temperature may be set between about 300 to 400° C.

Further, a PVD-metal silicide layer may be formed as a metal monosilicide type material, such as CoSi, TiSi, and NiSi. Alternatively, the PVD-metal silicide layer may be formed as a metal disilicide including CoSi2, TiSi2, or NiSi2. Those of ordinary skill in the art will understand that defined reaction conditions and selected materials will define these alternatives.

At this point, it should be more specifically noted that the silicon layer onto which the PVD-metal layer is formed may comprise a silicon substrate (semi-conducting or semi-insulating), doped source/drain regions of the substrate, or a predetermined material layer or film structure including a silicon component, such as, for example, a polysilicon gate structure.

After the PVD-metal layer is silicidated, a residual portion of the PVD-metal layer may remain un-silicidated. This residual portion is removed (S20). The residual portion of the PVD-metal layer may be removed, for example, by applying one or more wet etching processes, such as a wet etching process using a phosphoric acid, an acetic acid, and/or a nitric acid, as selected non-limiting examples.

Following removal of the residual portion of the PVD-metal layer, a CVD-metal layer is formed on the PVD-metal silicide layer using a CVD method (S30). As noted above, a MOCVD or the ALD method may be used to form the CVD-metal layer. In one embodiment, a CVD-metal layer is formed with a thickness ranging between about 5 to 300 Å.

As one possible example of a CVD-metal layer well adapted for use within the context of an embodiment of the invention, the formation of a CVD-cobalt layer will be described in some additional detail. As before, the choice of material(s) and/or deposition process(es) are merely exemplary.

First, a cobalt precursor is bubbled outside a process chamber so as to be vaporized. The cobalt precursor is present in a liquid state at normal temperature, and a thermally stable material is used as the precursor. Illustrative, but, non-limiting, examples of the metal precursor, particularly the cobalt precursor, which is capable of being used in the CVD method, may include materials expressed by the formula: Co2(CO)6(R1-C≡C—R2), where R1 includes H or CH3, and R2 includes hydrogen, t-butyl, phenyl, methyl, or ethyl. Other examples of the cobalt precursor may include Co2(CO)6(HC≡CtBu), Co2(CO)6(HC≡CPh), Co2(CO)6(HC≡CH), Co2(CO)6(HC≡CCH3), or Co2(CO)6(CH3C≡CCH3), or a mixture thereof.

Subsequently, the vaporized cobalt precursor is introduced into the process chamber having a semiconductor substrate loaded therein. Argon (Ar) gas may be used as a carrier gas to introduce the vaporized cobalt precursor into the process chamber. Vaporized cobalt precursor may be introduced, for example, at the flow rate of about 10 to 100 sccm, and the carrier gas may be provided at the flow rate of about 50 to 250 sccm. A CVD cobalt layer may be formed on a PVD cobalt silicide layer using this process.

When using a MOCVD process, in order to remove impurities which may be generated as a result of the reaction, a hydrogen plasma treatment may be applied during the MOCVD process or after its completion.

Following formation of the CVD-metal layer, a capping layer may be formed on the CVD-metal layer before application of a first heat treatment. The capping layer prevents impurities, such as natural oxide components, from forming on the exposed surface of the CVD-metal layer. However, if the process of forming the CVD-metal layer and the subsequent first heat treatment are conducted in situ, the process of forming a capping layer may be omitted. But in certain embodiments, the process of forming a capping layer may nonetheless be preferably despite the in situ nature of the related processes, such as for example, the formation of a CVD cobalt layer in situ.

One non-limiting example of a capping layer and a corresponding PVD deposition process will now be described. However, a CVD process or an ATD process might be used to equally good effect. Since PVD processes are typically performed in a vacuum, the pressure a process chamber may be set, for example, to about 10-6 to 10-3 Torr. A capping layer may then be formed having a thickness ranging from between about 10 to 300 Å, and in one embodiment, preferably to between about 50 to 300 Å. The capping layer may be formed, for example, from a titanium (Ti) layer, a titanium nitride (TiN) layer, or a composite layer of titanium and titanium nitride.

Following formation of the capping layer, where desired, a first heat treatment is applied to the combination of PVD-metal silicide layer and overlaying CVD-metal layer (S40).

The one or more metal component(s) of the CVD-metal layer and silicon from the silicon layer underlying the PVD-metal layer diffused together under the effect of the first heat treatment, while the PVD-metal silicide layer remains interposed between the CVD-metal layer and the silicon layer. That is, the CVD-metal layer is silicidated through the intervening PVD-metal silicide layer. The resulting CVD-metal silicide layer may comprise metal monosilicides and/or metal disilicides, as noted above, in accordance with defined reaction conditions.

In the silicidation process accomplished by the first heat treatment, it is possible to prevent the metal component(s) from the CVD-metal layer from being excessively diffused into the silicon layer because of the presence of the PVD-metal silicide layer. As a result, the thickness of the CVD-metal silicide layer and the resulting compound metal silicide layer (i.e., PVD metal silicide layer+CVD metal silicide layer) may be well controlled.

For example, the first heat treatment process may be conducted using a rapid thermal process (RTP) or a similar furnace process. Additionally, the first heat treatment may be conducted at a vacuum pressure ranging between an ultrahigh vacuum pressure to 5 Atms. The temperature of the first heat treatment process may be appropriately controlled in accordance with type of metal layer being used. For example, if the CVD metal layer is cobalt, the first heat treatment may be conducted at a temperature ranging from between about 400 to 600° C. in an atmosphere of inert gas, such as nitrogen, argon, or helium, or atmospheric gas.

In this context, the term “ultrahigh vacuum” denotes pressure in the heat treatment process chamber maintained at less than a few Torr, and in one embodiment between about 10⁻³ to 10⁻⁹ Torr. For an ultrahigh vacuum pressure around 10⁻³ Torr, nitrogen, argon, or helium may be used with good effect. If the ultrahigh pressure is 10⁻⁶ Torr or less, atmospheric gas may not be used with good effect. Furthermore, in order to maintain an ultrahigh vacuum pressure, the heat treatment process chamber must be continuously exhausted to account for out-gassing during the first heat treatment. Under these ultrahigh vacuum pressure and continually exhausted process chamber conditions, impurities such as oxygen and carbon activated by the first heat treatment may be effectively removed from the cobalt layer. Furthermore, any natural oxide layer formed on a surface of cobalt layer will also be removed (activated and exhausted) during the first heat treatment.

Next, any residual (un-silicidated) portion of the CVD-metal layer is removed (S50). As before, a conventional wet etching process may be applied to accomplish this removal, such as a wet etching process using a phosphoric acid, an acetic acid, and/or a nitrogen acid.

Subsequent to the removal of any residual portion of the CVD-metal layer, a second heat treatment is performed at a temperature higher than that of the first heat treatment (S60). Under the influence of the second heat treatment, silicidation of the PVD-metal silicide layer and the CVD-metal silicide layer is completed, and conversion into principally metal disilicides is obtained for the compound metal silicide layer. As metal disilicide-type layers generally have lower specific resistance than metal monosilicide-type layers, the resulting compound metal silicide layer enjoys performance benefits over conventional monosilicide-type layers.

Like the above-mentioned first heat treatment, the second heat treatment may be conducted at a vacuum pressure ranging between an ultrahigh vacuum pressure to 5 Atms. The temperature of the second heat treatment process may vary with the composition of the metal used to form the PVD-metal silicide layer and/or the CVD-metal silicide layer. In one embodiment, however, where cobalt is used, the second heat treatment is performed at a temperature of between about 700 to 900° C.

Where a metal silicide layer is formed in accordance with an embodiment of the invention consistent with the flowchart shown in FIG. 1, it is possible to form a very thin metal silicide layer. Further, the agglomeration that characterizes many conventional high temperature processes can be minimized, thereby improving thermal stability. As a result, in one practical application of the resulting metal silicide layer, a gate electrode may be formed with reduced surface resistance, and corresponding source/drain regions are characterized by reduced leakage current.

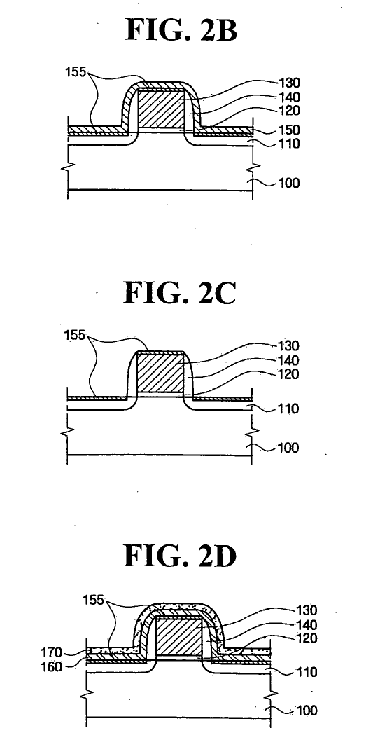

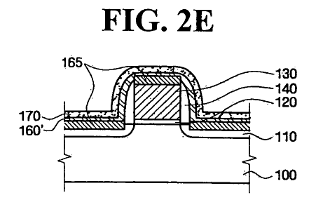

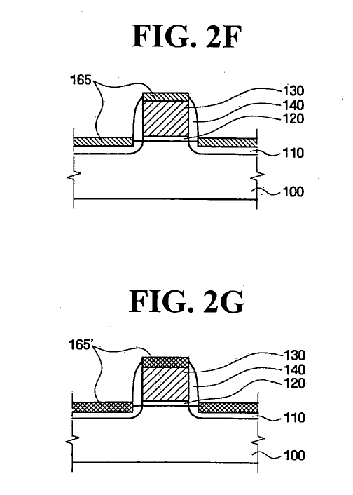

Hereinafter, an exemplary method of fabricating a semiconductor device according to an embodiment of the invention will be described referring to FIGS. 2A to 2G. In this exemplary method, a metal silicide layer may be formed as described above.

As shown in FIG. 2A, a polysilicon gate 130 is formed on a gate insulating layer 120 over a channel region between source/drain regions 110 formed in a silicon semiconductor substrate 100. In the illustrated example, source/drain regions 110 have an LDD structure, but other source/drain structures may be used. Sidewalls 140 are formed to protect the gate structure.

Next, as shown in FIG. 2B, a PVD-metal layer 150 is formed using a PVD process, as described, for example, above. In the illustrated example, a lower surface of PVD-metal layer 150 contacts an upper surface of polysilicon gate 130 and upper surfaces of source/drain regions 110. Using the silicidation process described above, for example, PVD-metal layer 150 is reacted with these underlying silicon layers almost as the deposition of PVD-metal layer 150 is accomplished. The silicidation reaction between the underlying silicon layers and PVD-metal layer 150 yields a thin PVD-metal silicide layer 155 formed on the upper surfaces of source/drain layers 110 and polysilicon gate 130. (The term “on” in this context refers generally to the silicidation process described above, wherein the metal silicide layer is actually formed at least partially “into” the underlying silicon layers to form a resulting metal silicide layer “on” same).

Next, as shown in FIG. 2C, the un-reacted residual portions of PVD-metal layer 150 are removed. Thereby, an upper surface of PVD-metal silicide layer 155 formed on the upper surfaces of polysilicon gate 130 and source/drain regions 110 is exposed. The removal of the residual PVD-metal layer 150 may be accomplished using a wet etching process making use of a phosphoric acid, an acetic acid, or a nitric acid, for example.

Subsequently, as shown in FIG. 2D, a CVD-metal layer 160 is formed on PVD-metal silicide layer 155 and sidewalls 140 using a CVD process. The illustrated example also includes an optional capping layer 170 formed from Ti, TiN, or a Ti/TiN composition formed on CVD-metal layer 160.

Following formation of the CVD-metal layer 160, a first heat treatment is performed. With reference to FIG. 2E, CVD-metal layer 160 is silicidated under the influence of the first heat treatment to form CVD-metal silicide layer 165.

The metal component of CVD-metal layer 160 and the silicon component of polysilicon gate 130 diffuse into one another while PVD-metal silicide layer 155 remains interposed there between. In this manner, CVD-metal silicide layer 165 is formed. In the illustrated example, at this point in the fabrication process the combination of CVD-metal silicide layer 165 and PVD-metal silicide layer 155 is illustrated as a single composite metal silicide layer 165.

Next, as shown in FIG. 2F, the un-reacted residual portion of CVD-metal layer 160, as well as the optionally provided capping layer 170 are removed. Thereby, an upper surface of composite metal silicide layer 165, as formed on the upper surfaces of polysilicon gate 130 and source/drain regions 110, is exposed. Here again, a wet etching process making use of a phosphoric acid, an acetic acid, or a nitric acid may be used.

As noted above, a second heat treatment may be performed at a temperature higher than the temperature of the first heat treatment at this point. With reference to FIG. 2G, the composite metal silicide layer 165 is further reacted with silicon components found in the underlying silicon layers under the influence of the second heat treatment to form a final composite metal silicide layer 165′. The final composite metal silicide layer mostly comprises metal disilicide components, but may also comprise some metal monosilicides.

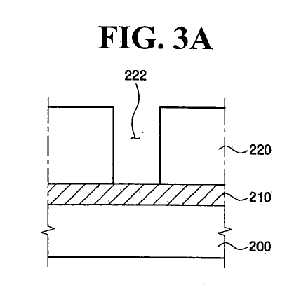

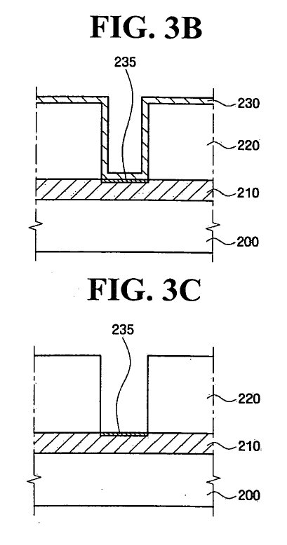

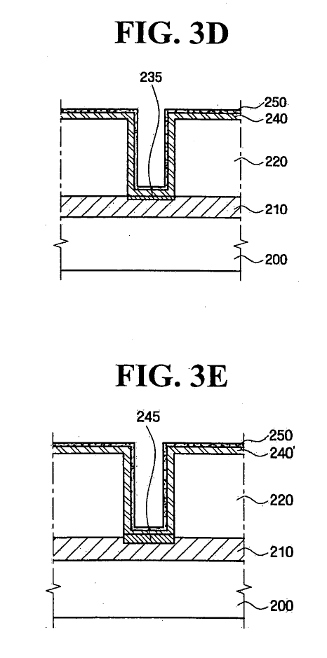

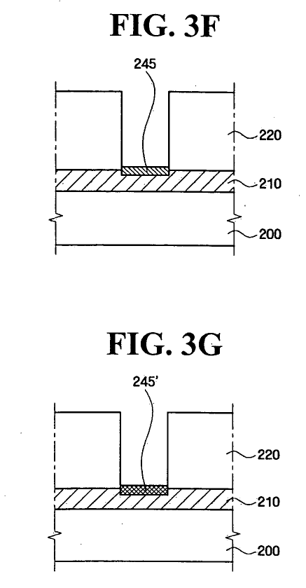

A method of fabricating a semiconductor device according to another embodiment of the invention will be described referring to FIGS. 3A to 3G.

First, as shown in FIG. 3A, an interlayer dielectric 220 is formed on a silicon layer 210 which is formed on a substrate 200. Next, interlayer dielectric 220 is etched to form a contact hole 222 which exposes an upper surface of silicon layer 210.

Next, as shown in FIG. 3B, a PVD-metal layer 230 is formed on the exposed upper surface of silicon layer 210 and on sidewalls of contact hole 222 using, for example, a high temperature PVD method. The portion of PVD-metal layer 230 contacting the exposed upper surface of silicon layer 210 is silicidated to form a PVD-metal silicide layer 235.

Subsequently, as shown in FIG. 3C, the un-reacted residual portions of PVD-metal layer 230 are removed. This may be accomplished, for example, using a wet etching process making use of a phosphoric acid, an acetic acid, or a nitric acid.

Next, as shown in FIG. 3D, a CVD-metal layer 240 is formed on PVD-metal silicide layer 235 and sidewalls of contact hole 222 using a CVD method. In the illustrated example, an optional capping layer 250 is also formed on CVD-metal layer 240.

At this point, a first heat treatment is performed. As shown in FIG. 3E, CVD-metal layer 240 is silicidated under the influence of the first heat treatment to form a CVD-metal silicide layer. As described above, the combination of the CVD-metal silicide layer and the PVD-metal silicide layer is illustrated as a single composite metal silicide layer 245.

Next, as shown in FIG. 3F, the un-reacted portions of CVD-metal layer 240 and capping layer 150 are removed. Again, a wet etching process making using of a phosphoric acid, an acetic acid, or a nitric acid may be used.

Subsequently, a second heat treatment is performed at a temperature higher than the temperature of the first heat treatment. With reference to FIG. 3G, the composite metal silicide layer 245 is further reacted with the silicon components of the underlying silicon layer under the influence of the second heat treatment to form a final composite metal silicide layer 245′. In this connection, final composite metal silicide layer 245′ mostly comprises metal disilicide components.

As with the gate structure elements described above, the contact formed in the foregoing example may be formed with a reduced thickness, thereby allowing increased overall integration of the incorporating semiconductor device. Reduced size and thickness of the resulting composite metal silicide layers notwithstanding, improved thermal stability may also be achieved.

Although the invention has been described in connection with the exemplary embodiments, it will be apparent to those skilled in the art that various modifications and changes may be made thereto without departing from the scope of the invention as defined by the following claims. Therefore, it should be understood that the above embodiments are not limiting, but illustrative in all aspects.

What is claimed is:

1. A method of forming a composite metal silicide layer comprising:
depositing a PVD-metal layer on a silicon layer using a Physical Vapor Deposition (PVD) process, and substantially simultaneously silicidating a portion of the PVD-metal layer contacting the silicon layer to form a PVD-metal silicide layer;
removing an un-reacted portion of the PVD-metal layer;
forming a CVD-metal layer on the PVD-metal silicide layer using a Chemical Vapor Deposition (CVD) process;
performing a first heat treatment to silicidate a portion of the CVD-metal layer contacting the PVD-metal silicide layer and thereby form a composite metal silicide layer;
removing an un-reacted residual portion of the CVD-metal layer; and
performing a second heat treatment on the composite metal silicide layer,
wherein the second heat treatment is performed at a higher temperature than the first heat treatment.

2. The method of claim 1, wherein at least one of the PVD-metal layer and the CVD metal layer comprises at least one the metal selected from a group consisting of Co, Ti, and Ni.

3. The method of claim 2, wherein at least one of the PVD-metal layer and the CVD metal layer comprises Co.

4. The method of claim 3, wherein the PVD process is conducted at a temperature ranging between about 300 to 400° C.

5. The method of claim 3, wherein the first heat treatment is performed at a temperature ranging between about 400 to 600° C., and the second heat treatment is performed at a temperature ranging between about 700 to 900° C.

6. The method of claim 1, wherein the PVD-metal silicide layer is formed to a thickness ranging between about 5 to 50 Å.

7. The method of claim 1, wherein the CVD-metal layer is deposited to a thickness ranging between about 5 to 300 Å.

8. The method of claim 1, further comprising:
forming a metal capping layer on the CVD-metal layer, the metal capping layer comprising at least one selected from a group consisting of Ti and TiN.

9. A method of fabricating a semiconductor device, comprising:
forming a gate structure comprising a polysilicon layer formed on a gate insulating layer over a channel region separating source/drain regions formed in a silicon substrate;
depositing a PVD-metal layer using a Physical Vapor Deposition (PVD) on upper surfaces of the polysilicon layer and the source/drain regions, and substantially simultaneously silicidating portions of the PVD-metal layer contacting the upper surfaces of the polysilicon layer and the source/drain regions to form a PVD metal silicide layer;
removing un-reacted portions of the PVD-metal layer;
forming a CVD-metal layer on the PVD-metal silicide layer;
performing a first heat treatment to silicidate portions of the CVD-metal layer contacting the PVD-metal silicide layer to form a composite metal silicide layer;
removing un-reacted portions of the CVD-metal layer; and
performing a second heat treatment on the composite metal silicide layer,
wherein the temperature of the second heat treatment is higher than the temperature of the first heat treatment.

10. The method of claim 9, wherein at least one of the PVD-metal layer and the CVD metal layer comprises at least one the metal selected from a group consisting of Co, Ti, and Ni.

11. The method of claim 10, wherein the PVD process is conducted at a temperature ranging between about 300 to 400° C.

12. The method of claim 10, wherein the first heat treatment is performed at a temperature ranging between about 400 to 600° C., and the second heat treatment is performed at a temperature ranging between about 700 to 900° C.

13. The method of claim 9, wherein the PVD metal silicide layer is formed to a thickness ranging between about 5 to 50 Å, and the CVD metal layer is formed to a thickness ranging between about 5 to 300 Å.

14. The method of claim 9, further comprising:
forming a metal capping layer on the CVD-metal layer, the metal capping layer comprising at least one selected from a group consisting of Ti and TiN.

15. A method of fabricating a semiconductor device, comprising:
forming an interlayer dielectric on a silicon layer;
etching the interlayer dielectric to form a contact hole exposing an upper surface of the silicon layer;
forming a PVD-metal layer on the exposed upper surface of the silicon layer using a Physical Vapor Deposition (PVD) method, and substantially simultaneously silicidating a portion of the PVD-metal layer contacting the exposed upper surface of the silicon layer to form a PVD metal silicide layer;
removing un-reacted portions of the PVD-metal layer;
forming a CVD-metal layer on the PVD-metal silicide layer;
performing a first heat treatment to silicidate a portion of the CVD-metal layer contacting the PVD-metal silicide layer to form a composite metal silicide layer;
removing un-reacted portions of the CVD-metal layer; and
performing a second heat treatment on the composite metal silicide layer, wherein the temperature of the second heat treatment is higher than the temperature of the first heat treatment.

16. The method of claim 15, wherein at least one of the PVD-metal layer and the CVD metal layer comprises at least one the metal selected from a group consisting of Co, Ti, and Ni.

17. The method of claim 16, wherein the PVD process is conducted at a temperature ranging between about 300 to 400° C.

18. The method of claim 16, wherein the first heat treatment is performed at a temperature ranging between about 400 to 600° C., and the second heat treatment is performed at a temperature ranging between about 700 to 900° C.

19. The method of claim 15, wherein the PVD metal silicide layer is formed to a thickness ranging between about 5 to 50 Å, and the CVD metal layer is formed to a thickness ranging between about 5 to 300 Å.

20. The method of claim 15, further comprising:
forming a metal capping layer on the CVD-metal layer, the metal capping layer comprising at least one selected from a group consisting of Ti and TiN.
